(19) United States
(12) Patent Application Publication
(10) Pub. No.: US 2005/0179031 A1
(43) Pub. Date: Aug. 18, 2005

(54) Organic semiconductor photodetector

(76) Inventors: Marco Sampietro, Como (IT); Giorgio Ferrari, Galliate (IT); Dario Natali, Torre Boldone (IT)

Correspondence Address: WENDEROTH, LIND & PONACK, L.L.P., 2033 K STREET N. W., SUITE 800, WASHINGTON, DC, 20006-1021, US

(21) Appl. No.: 10/503,728

(22) PCT Filed: Jan. 29, 2003
(86) PCT No.: PCT/EP03/00886

(30) Foreign Application Priority Data
Feb. 8, 2002 (IT) MI2002A 000231

(51) Int. Cl. H01L 35/24

(52) U.S. Cl. 257/40

(57) ABSTRACT

The present invention refers to a photodetector in particular of the type based on an organic semiconductor. In an embodiment the photodetector comprises a substrate (10) not electrically conductive having a first surface; characterized in that it comprises: a first (11) and a second (12) conductive electrode deposited on said first surface; an organic semi conductive material (13) deposited on said first surface in contact with said first (11) and second (12) conductive electrodes.

The present invention refers to a photodetector in particular of the type

based on an organic semiconductor. The use of organic semiconductor polymers is known in the photodetector sector, such as in the U.S. Pat. No. 5,698,048. It describes a photodetector made up in sequence of a conductor layer of aluminum, a layer of polymer having photosensitive properties, a transparent conductor layer of indium/tin oxide (ITO), and then a layer of glass that acts as substrate. The terminals for connecting the photodetector to the external measuring circuits are applied to the two conductor layers. The light passes through the glass, the transparent conductor layer and hits the layer of photosensitive polymer, activating it.

In view of the state of the art described, an object of the present invention is to provide a photodetector that is simpler to construct and more versatile.

In accordance with the present invention, this and other objects are achieved by means of a photodetector comprising a not electrically conductive substrate having a first surface; characterized in that it comprises: a first and a second conductive electrode deposited on said first surface; an organic semi conductive material deposited on said first surface in contact with said first and second conductive electrodes.

Thanks to the present invention a planar type photodetector can be constructed whose active part receives the light directly without material placed therebetween, therefore the electrodes and the substrate do not need to be transparent. With the structure of the present invention an extremely small capacity between the electrodes is obtained and thus the resolution in reading the electric signal is considerable. In addition the deposit of the electrodes can be carried out before the deposit of the organic material that is sensitive to the light and thus the two technologies can be optimized without disturbing each other.

The characteristics and advantages of the present invention will appear evident from the following detailed description of an embodiment thereof, illustrated as non-limiting example in the enclosed drawings, in which:

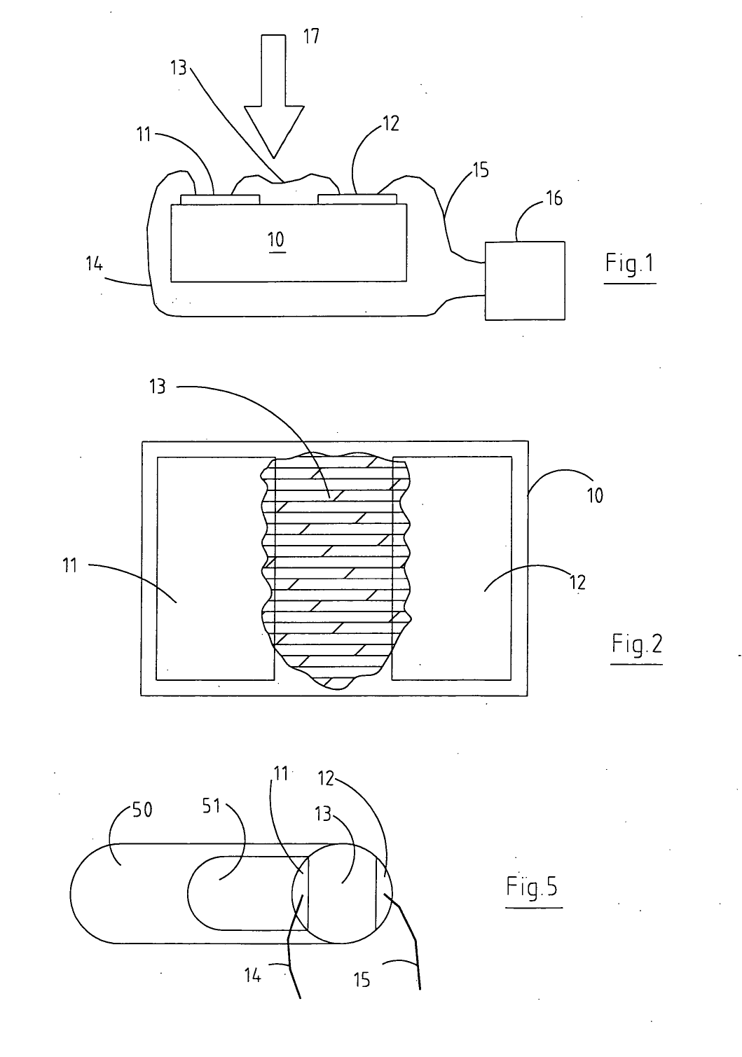

FIG. 1 represents, schematically, the structure from a side view of a photodetector in accordance with the present invention;

FIG. 2 represents, schematically, the structure of a first embodiment of the electrodes of a photodetector in accordance with the present invention;

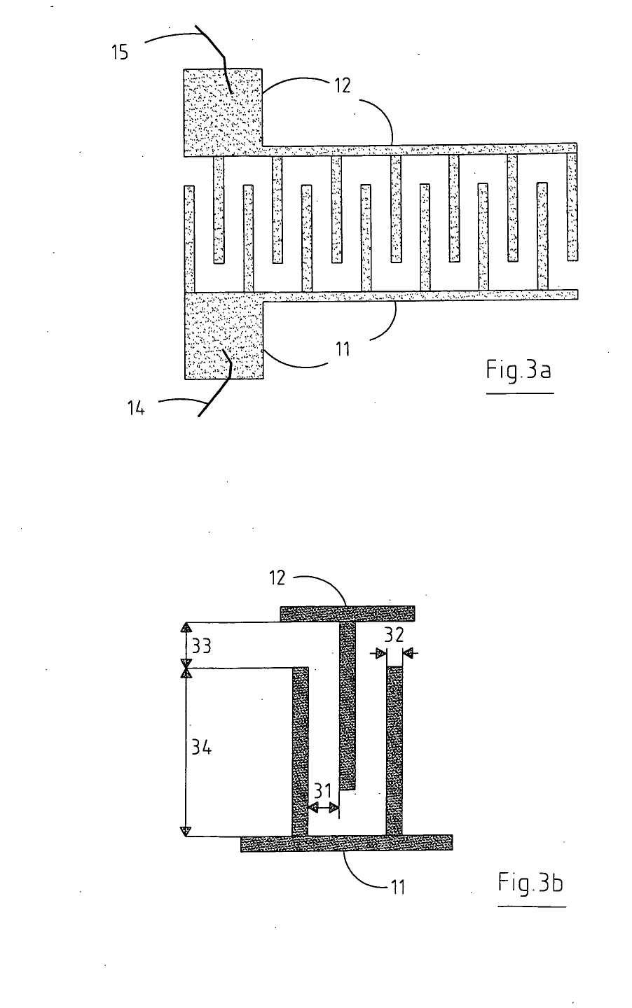

FIGS. 3A and 3B represent, schematically, the structure of a second embodiment of the electrodes of a photodetector in accordance with the present invention;

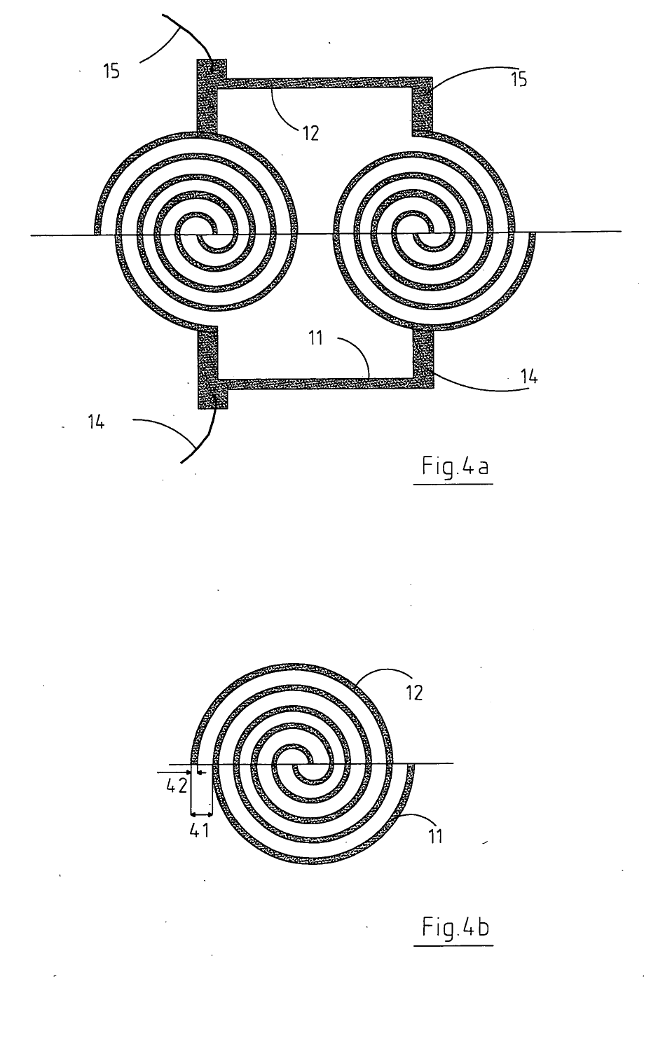

FIGS. 4A and 4B represent, schematically, the structure of a third embodiment of the electrodes of a photodetector in accordance with the present invention;

FIG. 5 represents, schematically a photodetector in accordance with the present invention constructed on an extremity of an optical fiber.

Now in reference to FIG. 1 that represents, schematically, the structure of a photodetector in accordance with the present invention a substrate 10 can be noted on which, on an upper surface, are deposited a first 11 and a second 12 conductive material, having the function of electrodes, arranged at a preset distance from each other. Still on the upper surface of the substrate 10 a layer of organic semi conductive material 13 is deposited so that it is in contact with the first 11 and the second 12 conductive material. The organic semiconductor 13 is deposited on the substrate 10 so as to at least cover partially the electrodes 11 and 12. The electrodes 11 and 12 are connected to two terminals, respectively 14 and 15 suitable for being connected to an external circuit 16 of polarization of the measuring and processing photodetector of the signal produced. Actually a planar conductor-semiconductor-conductor structure is constructed on a surface of the substrate 10, where the light 17 can be directly incident above the organic semi conductive material 13.

The substrate 10 can be made up of any non-electrically conductive material for example quartz, glass, silicon, silicon oxide, silicon nitride, plastic, fabric, wood, paper. The substrate 10 can thus be rigid or flexible and its surface is not necessarily flat and smooth. Clearly if the substrate is a transparent material the light can reach the organic semi conductive material 13 from both sides.

The material of the electrodes 11 and 12 can be made up of any electrically conductive material, compatibly with the material used for the organic semi conductive material 13, for example conductor metals (aluminum, silver, gold), organic conductive materials, conductor oxides (for example indium and tin oxide), graphite and conductive pastes.

So as to diminish the leakage current the electrodes 11 and 12 can be made up of two conducting materials different from each other, one for the electrode connected to the more positive potential, and another one for the electrode connected to the more negative potential. The material is to be chosen so as to have a suitable work function in relation to the organic semiconductor used, such to reduce the passage of charge when polarized without incident light.

The organic semi conductive material 13 can be made up for example of mLPPP (methyl substituted Ladder type Poly Para Phenylene) particularly suitable for the absorption of ultra-violet radiation with wavelength lower than 450 nm, or of PPV—Poly-PhenyleneVinylene particularly suitable for absorption wavelengths in the visible with wavelength between 350 nm and 520 nm, or of substituted dithiolene metal particularly suitable for the absorption of radiation in the near infrared, with lengths between 850 nm and 1100 nm, and however any organic semi-conductive material sensitive to ultraviolet radiations and/or visible and/or infrared (of wavelengths between about 100 nm and 1700 nm).

In an embodiment of the invention according to the structure of FIGS. 1 and 2, a substrate 10 of quartz (1 cm×1 cm×0.5 mm) has been used on which gold electrodes 11 and 12 have been deposited. To improve the adhesion of the gold on the quartz a layer of 20 nm of chromium oxide and then a layer of gold of 25 nm has been deposited. The deposit of the layers of oxide and of gold comes about by means of sputtering and photolithography. A layer of between 150 nm and 300 nm of dithiolene has been cast as organic semiconductor 13.

Other construction processes of the photodetector can be used, in relation to the materials used, well known to a technician in the sector.

We now refer to FIG. 2 that represents, schematically, the structure of a first embodiment of the electrodes of a photodetector in accordance with the present invention. In this case two electrically conductive electrodes 11 and 12 are rectangles and are deposited on a substrate 10 with a rectangular shape. The organic semi conductive material 13 has been arranged between them.

In alternative the substrate 10 can be of any other shape, for example circular (as can be seen in FIG. 5) and the two electrically conductive electrodes 11 and 12 are circle portions enclosed by a cord. The electrodes 11 and 12 have to be placed at a distance from each other so as to be able to produce an electric field in the semi conductive material 13 which is big enough to efficiently convey the photo generated charge to the same electrodes.

FIGS. 3A and 3B represent, schematically, the structure of a second embodiment of the electrodes of a photodetector in accordance with the present invention. In particular, in FIG. 3A a structure of the electrodes of the intertwined type can be seen, that is the fingers of the electrode 12 are inserted into the spaces left by the fingers of the electrode 11 and also two more ample zones to be able to fasten the terminals 14 and 15 can be seen. In FIG. 3B a portion of FIG. 3A can be seen, where D defines the distance 31 between one finger of the electrode 12 and a finger of the electrode 11 and L the length 34 of a finger, the distance 33 between an extremity of an electrode and the opposed electrode is preferably equal to 2D, and however to such a distance that limits any possible tip effects. The width 32 of a finger is the smallest possible that the construction technology permits, so that the surface of the substrate 10 is mainly occupied by the photosensitive organic semi conductive material 13, so as to have the maximum efficiency in gathering light. The number of fingers of each electrode can freely be chosen in compatibility with the dimensions of the substrate 10. The length 34 of a finger can be any length, as long as the ratio maintains the resistance of the finger low. For example, in an embodiment of the invention the length 34 of a finger is L=100 m, the width 32 of 1 m and the distance 31 between the electrodes D=6 m.

FIGS. 4A and 4B schematically represent the structure of a third embodiment of the electrodes of a photodetector in accordance with the present invention. In particular, in FIG. 4A, a spiral type of structure of the electrodes can be seen, that is the electrode 11 forms a spiral and the electrode 12 forms another spiral placed inside the spiral of the electrode 11. Two zones can also be seen, outside the spirals, which are wider so as to fasten the terminals 14 and 15. A portion of FIG. 4A can be seen in FIG. 4B. The distance 41 between one spiral and the other, the width 42 of an electrode and the length of the spiral are subject to the same project rules shown in relation to FIG. 3.

The electrodes 11 and 12 can be made up of one or more couples of spirals interconnected depending on the dimensions and the forms that the substrate 10 can have.

FIG. 5 schematically represents a photodetector in accordance with the present invention constructed on an extremity of an optical fiber.

The photodetector is in this case constructed on a cutting surface of an optical fiber 50, that is the substrate in this case is an optical fiber 50.

In this case the light arrives directly via an optical fiber on the organic semi conductive material 13. The electrodes 11 and 12 in this case can be either of the type in FIG. 5 or for example the spiral type in FIG. 4.

To facilitate fastening the two terminals 14 and 15, or any other connection means, in consideration of the dimensions of an optical fiber, provision can be made to deposit the conductive material of the electrodes 11 and 12 also on the side surface of the fiber itself as can be seen in the portion 51 for the electrode 11. In this manner a wider surface is made available for the connection of the two terminals 14 and 15, or any other connection means, to the photodetector.

The current photodetectors of inorganic semiconductor (Si, GaAs etc.) are devices in themselves mounted in the receiver. Each photodetector has to be aligned with the corresponding optical fiber. Also in the hypothesis of perfect alignment between fiber and detector, one part of the optical power available in fiber has no incidence on the sensitive area of the detector because of the index differences of refraction to the fiber-air and air-detector interfaces. All a possible misalignment between fiber and detector does is to accentuate such losses. The detector in accordance with the present invention is instead directly integrated on the optical fiber and therefore does not suffer from losses of beams by geometric effects. As the active material is made up of an organic semiconductor, it has a refraction index that is very similar to that of the fiber, thus minimizing also the losses by reflection at the interfaces. Having an optical fiber available with one extremity equipped with the detector, the positioning in the connection stage of the optical fiber cable will have to be done from the arrival point (receiver) towards the departure point (transmitter) where the fiber can be cut to measure on site.

An example of an optical fiber with an integrated photodetector has been given, but in accordance with the present invention, the photodetector can also be applied directly onto a printed circuit or onto an integrated circuit, independently of the devices and the circuits constructed in the integrated below the photodetector.

In this manner, starting from an electronic circuit in silicon by simple deposit of the organic material sensitive to the light an integrated optic electronic micro system can be obtained.

Nothing prohibits the application of a plurality of photodetectors on the above mentioned substrates in any spatial arrangement (linear or matrix) depending on the specific application.

1. Photodetector comprising:
a not electrically conductive substrate (10) having a first surface;
a first (11) and a second (12) conductive electrode; an organic semiconductive material (13);
wherein said first (11) and second (12) conductive electrode are deposited on said first surface at a preset distance from each other to form a planar structure;
said organic semi conductive material (13) is deposited on said first surface in contact with and also at least cover partially said first (11) and second (12) conductive electrodes.

2. Photodetector in accordance with claim 1, wherein said organic semiconductor material (13) is sensitive to the radiations of wavelength of between 100 nm and 1700 nm.

3. Photodetector in accordance with claim 1, wherein said first (11) and second (12) conductive electrode is chosen from between the following materials: conductor metals, organic conductive materials, conductive oxides, graphite and conductive pastes.

4. Photodetector in accordance with claim 1, wherein said first (11) and second (12) conductive electrode are made up of the same material.

5. Photodetector in accordance with claim 1, wherein said first (11) and second (12) conductive electrode are made up of different materials.

6. Photodetector in accordance with claim 1, wherein said first (11) and second (12) conductive electrode are made up of an intertwined structure.

7. Photodetector in accordance with claim 1, wherein said first conductive electrode (11) is made up of a spiral structure, said second conductive electrode (12) is made up of a spiral structure and that said spirals are wound between themselves.

8. Photodetector in accordance with claim 1, wherein non-conductive said substrate (10) is chosen from between the following materials: quartz, glass, silicon, silicon oxide, silicon nitride, plastic, fabric, wood, paper.

9. Photodetector in accordance with claim 1, wherein said first surface of said non-conductive substrate (10) is made up of the cutting surface of an optical fiber (50).

10. Photodetector in accordance with claim 1, wherein said first surface of said non-conductive substrate (10) is made up of a printed circuit.

11. Photodetector in accordance with claim 1, wherein said first surface of said non-conductive substrate (10) is made up of an integrated circuit.

12. Photodetector in accordance with claim 1, wherein said semi conductive organic material (13) is chosen from between the following materials: PPV, metal dithiolene, mLPPP.

13. Photodetection system comprising a plurality of photodetectors according to the claim 1.

14. System in accordance with claim 13, wherein said plurality of photodetectors is arranged in any spatial arrangement.

15. System in accordance with claim 13, wherein said nonconductive substrate (10) is made up of an integrated circuit.
